(19) United States
(12) Patent Application Publication
(10) Pub. No.: US 2026/0282291 A1
(43) Pub. Date: Sep. 17, 2026

(54) Selective Isolation of Interconnectable Cooling System Modules

(71) Applicant: Oracle International Corporation, Redwood Shores, CA (US)

(72) Inventors: Joshua (JP) Michael Buzzell, Providence Forge, VA (US); Craig Alderson Pennington, San Francisco, CA (US); Vali Sorell, Charlotte, NC (US); Chris Palmer, Woodley (GB); Heyang Chen, Newark, CA (US)

(73) Assignee: Oracle International Corporation, Redwood Shores, CA (US)

(21) Appl. No.: 19/423,778

(22) Filed: Dec. 17, 2025

Related U.S. Application Data
(60) Provisional application No. 63/771,275, filed on Mar. 13, 2025.

(51) Int. Cl. H05K 7/20

(52) U.S. Cl. CPC H05K 7/20781; H05K 7/20272; H05K 7/20836

(57) ABSTRACT

Techniques for selectively isolating interconnectable modules in a coolant system are disclosed. A system directs a flow of coolant liquid through coolant pipe assembly racks mounted in a data center pod. The racks store heat-generating computing devices. The coolant pipe assembly may be configured as a loop-shaped structure. One side of the loop may supply coolant liquid to one row of racks, and another side of the loop may supply coolant liquid to another row of racks. The system closes a set of valves along a coolant pipe to isolate a set of target racks from the flow of coolant liquid. Due to the loop structure of the coolant pipe assembly, the system continues to direct coolant liquid to other racks in the same row of the loop-shaped structure as the isolated target racks.

### BENEFIT CLAIMS; RELATED APPLICATIONS; INCORPORATION BY REFERENCE

This application claims the benefit of U.S. Provisional Patent Application 63/771,275, filed Mar. 13, 2025, that is hereby incorporated by reference.

The Applicant hereby rescinds any disclaimer of claim scope in the parent application(s) or the prosecution history thereof and advises the USPTO that the claims in this application may be broader than any claim in the parent application(s).

### TECHNICAL FIELD

The present disclosure relates to data center storage. In particular, the present disclosure relates to interconnectable modular data center storage and cooling systems.

### BACKGROUND

Cooling systems are a critical component in data center environments. Servers and networking equipment can generate a significant amount of heat. Overheated components can malfunction or fail, leading to potential data loss and costly repairs or replacements. High temperatures can also cause equipment to throttle performance to prevent damage. Thus, effective cooling systems can help ensure that hardware operates at optimal capacity. The increasing demand for AI workloads, which generate more heat than traditional applications, is driving the adoption of more efficient cooling solutions like liquid cooling.

The approaches described in this section are approaches that could be pursued but not necessarily approaches that have been previously conceived or pursued. Therefore, unless otherwise indicated, it should not be assumed that any of the approaches described in this section qualify as prior art merely by virtue of their inclusion in this section.

### BRIEF DESCRIPTION OF THE DRAWINGS

The embodiments are illustrated by way of example and not by way of limitation in the figures of the accompanying drawings. References to “an” or “one” embodiment in this disclosure are not necessarily to the same embodiment, and they mean at least one. In the drawings:

FIG. 1 illustrates a data center system in accordance with one or more embodiments;

FIG. 2 illustrates a cooling system infrastructure for a data center in accordance with one or more embodiments;

FIG. 3A is a perspective view of a data center pod in accordance with one or more embodiments;

FIG. 3B is a side view of a data center pod in accordance with one or more embodiments;

FIG. 3C is a side view of an interconnectable data center pod module in accordance with one or more embodiments;

FIG. 3D is an end view of an interconnectable data center pod module in accordance with one or more embodiments;

FIG. 3E is a cut-out view of an interconnectable data center pod module in accordance with one or more embodiments;

FIG. 4 illustrates a data center pod cooling system in accordance with one or more embodiments;

FIG. 5 illustrates a data center pod cooling system in accordance with one or more embodiments;

FIG. 6 illustrates a data center cooling system in accordance with one or more embodiments;

FIG. 7 illustrates an example set of operations for isolating and connecting segments in a liquid cooling system according to one or more embodiments in accordance with one or more embodiments; and

FIG. 8 is a hardware system in accordance with one or more embodiments.

### DETAILED DESCRIPTION

In the following description, for the purposes of explanation, numerous specific details are set forth to provide a thorough understanding. One or more embodiments may be practiced without these specific details. Features described in one embodiment may be combined with features described in a different embodiment. In some examples, well-known structures and devices are described with reference to a block diagram form to avoid unnecessarily obscuring the present disclosure.

The term “cloud computing service” or “cloud service” is generally used to refer to a service that is made available by a cloud services provider (CSP) to users or customers on demand (e.g., via a subscription model) using systems and infrastructure (cloud infrastructure) provided by the CSP.

In most cases, the CSP is a third-party service that specializes in providing (e.g., offering, renting, selling) cloud services to customers. The servers and systems that make up the CSP's infrastructure are separate from the customer's own on-premise servers and systems. Customers can thus avail themselves of cloud services provided by the CSP without having to purchase separate hardware and software resources for the services. Cloud services are designed to provide a subscribing customer easy, scalable access to applications and computing resources without the customer having to invest in procuring the infrastructure that is used for providing the services. In some instances, an entity might opt to deploy a private cloud, becoming its own provider of cloud services. In some instances, an entity may utilize both a private cloud and a public cloud provided by a third-party CSP, thereby forming a hybrid cloud.

There are several cloud service providers that offer various types of cloud services. There are various different types or models of cloud services including Software-as-a-Service (SaaS), Platform-as-a-Service (PaaS), Infrastructure-as-a-Service (IaaS), and others. In an IaaS model, the CSP provides infrastructure (referred to as “cloud services provider infrastructure” or “CSPI”) that can be used by customers to build their own customizable networks and deploy customer resources.

A customer can subscribe to one or more cloud services provided by a CSP. The customer can be any entity, and the like. When a customer subscribes to or registers for a service provided by a CSP, a tenancy, or an account, is created for that customer. The customer can then, via this account, access the subscribed-to one or more cloud resources associated with the account.

### TABLE OF CONTENTS

1. GENERAL OVERVIEW
2. INTERCONNECTABLE MODULAR STORAGE AND COOLING SYSTEM ARCHITECTURE
3. CONNECTING AND ISOLATING COMPONENTS IN MODULAR COOLING SYSTEM
4. COMPUTER SYSTEM
5. MISCELLANEOUS; EXTENSIONS

### 1. General Overview

Embodiments provide interconnectable data center pod modules that include independent frames defining compartments, cable support segments, and pipe support segments. Multiple pod modules are interconnected side-by-side to form a data center pod. Multiple pods are selectively connected together with controllable valves to manage coolant liquid flow and temperature within and between data center pods. Embodiments include valves located along coolant supply pipes mounted on the pipe support segments and supported by a data center pod frame. Valves may be located along the coolant supply pipes or between pipe segments to interconnect the cooling pipe segments of adjacent data center pod modules. The selective closing of valves allows for isolating computing devices in compartments of pod modules from the coolant pipes. In some embodiments, the coolant supply pipes are configured in a loop configuration. When valves are open, coolant may flow through a section of the coolant supply pipe in a first direction to supply coolant to racks in pod modules. When a set of valves is closed to isolate a subset of pod modules from the coolant liquid flow, the coolant liquid may continue to be supplied to other racks and pod modules in the data center pod by flowing in an opposite direction through the section of the coolant supply pipe.

One or more embodiments selectively isolate data center pod modules from a coolant liquid flow through coolant pipes using sets of valves. A system directs a flow of coolant liquid through a coolant supply pipe. The pipe may be configured as a loop-shaped structure. One side of the loop may supply coolant liquid to racks mounted in a set of pod modules, while another side of the loop may supply the coolant liquid to racks mounted in the set of pod modules on an opposite side of an aisle extending along the pod modules. The system may identify a triggering event to isolate one or more racks or pod modules. For example, the system may identify a cluster of servers in a data center that require maintenance or replacement. The system closes a set of valves along the coolant supply pipe to isolate a target pod module or rack from a coolant liquid flow. Due to the loop structure of the coolant supply pipe, the system continues to direct coolant liquid to other racks on the same side of the loop-shaped coolant pipe structure as the isolated racks. Based on determining completion of the triggering event, the system opens the valves to allow coolant liquid flow to the isolated racks and pod modules.

One or more embodiments selectively isolate data center pod cooling systems from each other. A data center pod cooling system includes a cooling unit and coolant supply pipes to supply coolant liquid to racks in data center pod modules. Coolant return pipes return heated coolant liquid from the racks to the cooling unit for cooling and recycling. Data center pod cooling systems are interconnected with valves. A system selectively opens and closes the valves to selectively allow or prevent liquid coolant flow between adjacent data center pod cooling systems. For example, a data center management system may determine that equipment requires servicing or replacement in one pod. A valve may require replacement, a cooling unit may require servicing, or computing components of a server mounted in a rack of a pod module may require replacement. The system closes a set of valves to isolate the target equipment from coolant liquid flow. Closing the set of valves may result in preventing one or more racks from circulating coolant liquid through the coolant liquid system of the data center pod. The data center management system may open valves between the data center pod cooling system and an adjacent data center pod cooling system to allow coolant liquid to flow between the cooling systems. The flow of coolant liquid between the cooling systems may provide coolant liquid to racks that were isolated from coolant liquid circulation flow when the inter-pod valves were closed.

One or more embodiments described in this Specification and/or recited in the claims may not be included in this General Overview section.

### 2. Interconnectable Modular Storage and Cooling System Architecture

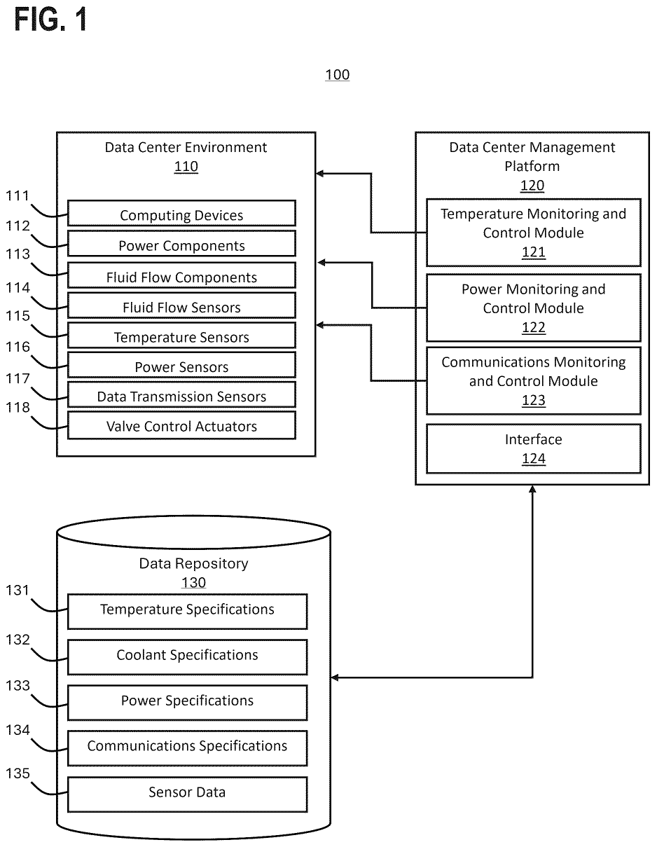

FIG. 1 illustrates a system 100 in accordance with one or more embodiments. As illustrated in FIG. 1, system 100 includes data center environment 110, a data center management platform 120, and a data repository 130. In one or more embodiments, the system 100 may include more or fewer components than the components illustrated in FIG. 1. The components illustrated in FIG. 1 may be local to or remote from each other. The components illustrated in FIG. 1 may be implemented in software and/or hardware. Each component may be distributed over multiple applications and/or machines. Multiple components may be combined into one application and/or machine. Operations described with respect to one component may instead be performed by another component.

The data center environment 110 includes computing devices 111, including network servers, graphics processing unit (GPU) servers, network switches, load balancers, and other computing devices that facilitate the storage and transmission of data over a network between data center computing devices 111 and external computing devices. Power components 112 include a remote power panel system (RPPS). The RPPS is an electrical distribution unit that provides a power to server racks and network equipment from a centralized location. Fluid flow components 113 include a cooling unit and pipes for directing fluid from the cooling unit to network equipment and from the network equipment to the cooling unit.

The data center environment 110 includes a variety of sensors for monitoring data transmission, power, and fluid flow. Sensors include fluid flow sensors 114 that measure the flow of fluid through pipes that run along rows of server racks. Examples of fluid flow sensors include differential pressure sensors, thermal mass flow sensors, and ultrasonic flowmeters. The fluid flow sensors 114 monitor cooling systems that utilize liquids or fluids, such as water, air, or chemical coolant. The fluid flow sensors 114 monitor flow rates and identify potential leaks.

Temperature sensors 115 measure the temperature inside the data center environment 110 and/or on or in particular pieces of network equipment. Examples of temperature sensors 115 include thermistors, resistance temperature detectors (RTDs), and thermocouples. The temperature sensors 115 measure ambient air, rack intake/exhaust, and coolant liquid temperatures. Temperature sensors 115 are placed to ensure precise monitoring and efficient cooling management. Temperature sensors 115 are installed on server racks at the front (top, middle, and bottom) and back to track air intake and exhaust temperatures. Additional temperature sensors 115 are distributed throughout the data center environment 110 for environmental monitoring, capturing data on overall thermal and moisture or humidity conditions. Temperature sensors 115 may include immersion sensors that measure the temperature of cooling liquids within the cooling systems, while external sensors monitor components, such as cooling towers and exhaust points, to provide a complete picture of the data center's thermal environment.

Power sensors 116 measure power into the data center environment 110 and to particular pieces of network equipment. Power sensors 116 are used to monitor and manage the distribution and consumption of electrical energy across all systems in the data center environment 110. Power sensors 116 track numerous parameters, such as voltage, current, power factor, and energy usage, at various points in data center systems, including at individual servers, racks, power distribution units (PDUs), and uninterruptible power supplies (UPS). Power sensors 116 provide real-time data to enable operators to identify inefficiencies, detect abnormal loads, prevent equipment overloads, and ensure balanced power distribution. Real-time and accurate power data is critical for optimizing energy efficiency, maintaining uptime, and supporting capacity planning within the data center's power infrastructure.

Data transmission sensors 117 monitor data transmission to and from network equipment. Examples of data transmission sensors 117 include optical power meters, photodiode sensors, network interface card (NIC) sensors, transceivers, small form-factor pluggable (SFP) modules, ethernet performance monitors, link integrity sensors, continuity sensors, and environmental-network hybrid sensors. Data transmission sensors 117 monitor the performance, reliability, and integrity of network connections that carry data between servers, storage devices, and external networks. These sensors measure various parameters, such as signal strength, transmission speed, packet loss, latency, and error rates across network cables and fiber links. By continuously collecting and analyzing this information, data transmission sensors help detect issues like congestion, degraded connections, or hardware faults before they impact operations. They also support load balancing, optimize bandwidth usage, and ensure compliance with performance standards, contributing to the overall efficiency and stability of the data center's communication infrastructure.

Valve control actuators 118 convert an input control signal—electrical, pneumatic (air pressure), or hydraulic (fluid pressure)—into mechanical motion that opens, closes, or modulates a valve's position. In an embodiment, the valve control actuators 118 precisely control the flow of liquids through valves located along cooling pipes and exhaust pipes among the fluid flow components 113. The valve control actuators 118 may receive control signals for controlling the fluid flow through the values from the data center management platform 120.

The data center management platform 120 manages the performance of monitoring and control systems in the data center environment 110. A temperature monitoring and control module 121 receives temperature information from the temperature sensors 115 and controls environmental air conditioning systems or localized network device cooling systems to manage temperatures in the data center environment 110. The temperature monitoring and control module 121 may also receive fluid flow information from fluid flow sensors 114 and control valves, cooling units, or one or more pumps based on the received fluid flow information. For example, an immersive temperature sensor located in a cooling pipe attached to a cooling unit may measure a temperature that exceeds temperature specifications 131 and/or coolant specifications 132. The temperature monitoring and control module 121 may control the cooling unit to operate at a lower temperature. Additionally, or alternatively, the temperature monitoring and control module 121 may generate a control signal to a valve control actuator 118 to open a valve to an adjacent cooling system to allow additional cooling liquid to mix with the liquid in the target cooling system.

A power monitoring and control module 122 obtains data from power sensors 116 to ensure network components and data center equipment are receiving appropriate and stable power according to power specifications 133. If the power monitoring and control module 122 detects power abnormalities, it may shut down power to one or more components or generate notifications to a data center operator to diagnose power issues.

A communications monitoring and control module 123 obtains data from data transmission sensors 117 to ensure data is transmitted to and from network communications components according to communications specifications 134. For example, the communications monitoring and control module 123 may initiate remediation operations based on detecting a server associated with data communications delays that exceed threshold levels of communications delays.

In one or more embodiments, interface 124 refers to hardware and/or software configured to facilitate communications between a user and the data center management platform 120. Interface 124 renders user interface elements and receives input via user interface elements. Examples of interfaces include a graphical user interface (GUI), a command line interface (CLI), a haptic interface, and a voice command interface. Examples of user interface elements include checkboxes, radio buttons, dropdown lists, list boxes, buttons, toggles, text fields, date and time selectors, command lines, sliders, pages, and forms.

In an embodiment, different components of interface 124 are specified in different languages. The behavior of user interface elements is specified in a dynamic programming language such as JavaScript. The content of user interface elements is specified in a markup language, such as hypertext markup language (HTML) or XML User Interface Language (XUL). The layout of user interface elements is specified in a style sheet language such as Cascading Style Sheets (CSS). Alternatively, interface 124 is specified in one or more other languages, such as Java, C, or C++.

The system stores sensor data 135 from the sensors 114-117. The modules 121-123 may analyze and monitor the sensor data 135 to control devices and components in the data center environment 110. In addition, or in the alternative, the data center management platform 120 may analyze sensor data over time to predict power, temperature, fluid, and/or data transmission characteristics.

In one or more embodiments, a data repository 130 is any type of storage unit and/or device (e.g., a file system, database, collection of tables, or any other storage mechanism) for storing data. Furthermore, a data repository 130 may include multiple different storage units and/or devices. The multiple different storage units and/or devices may or may not be of the same type or located at the same physical site. Furthermore, a data repository 130 may be implemented or executed on the same computing system as the data center management platform 120. Additionally, or alternatively, a data repository 130 may be implemented or executed on a computing system separate from the data center management platform 120. The data repository 130 may be communicatively coupled to the data center management platform 120 via a direct connection or via a network. Furthermore, data sets illustrated within the data repository 130 may include may be implemented across any of components within the system 100 in a decentralized and/or distributed manner. The data sets are illustrated within the data repository 130 for purposes of clarity and explanation.

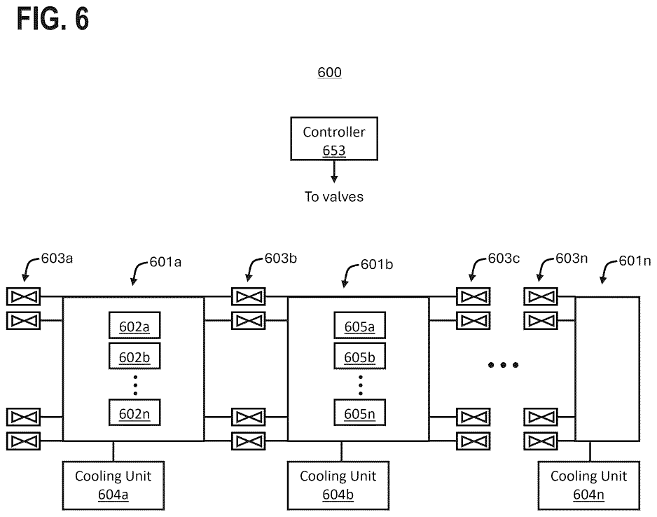

In one or more embodiments, data center management platform 120 refers to hardware and/or software configured to perform operations described herein for monitoring and controlling data center systems, including cooling, power, and data transmission systems. In embodiments, controlling data center systems includes controlling fluid flow through cooling pipes by controlling the open and closed states of valves along the cooling pipes. Examples of operations for connecting and isolating modules in a modular cooling system are described below with reference to FIG. 6.

In an embodiment, the data center management platform 120 is implemented on one or more digital devices. The term “digital device” generally refers to any hardware device that includes a processor. A digital device may refer to a physical device executing an application or a virtual machine. Examples of digital devices include a computer, a tablet, a laptop, a desktop, a server, and a mainframe.

### Cooling System Infrastructure for a Data Center

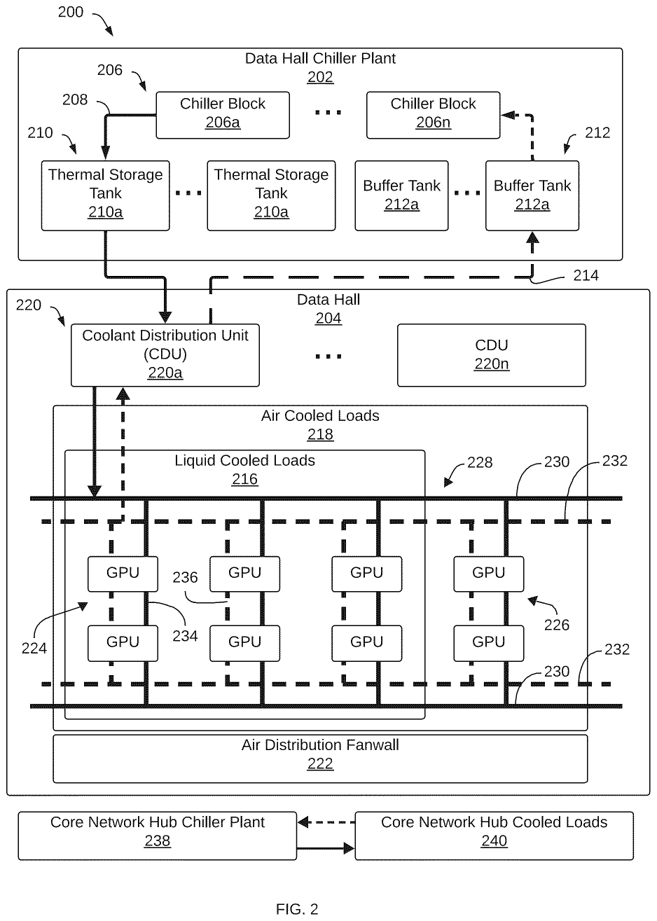

Referring to FIG. 2, example cooling system infrastructure for a data center is further described. As shown in FIG. 2, a cooling system infrastructure 200 for a data center includes a chiller plant 202. The chiller plant 202 chills cooling liquid and supplies the chilled cooling liquid to one or more data halls such as data hall 204. The data hall chiller plant includes multiple chiller blocks 206, such as chiller block 206a and chiller block 206n. The chiller blocks 206 include a set of chillers, respectively, for chilling the cooling liquid. The chillers may be air-cooled chillers. The chiller block 206 may include a redundant number of chillers. For example, the redundant number of chillers may correspond to an N+1 or an N+M redundancy model, where (N) is the number of chillers required to meet the cooling demands of the one or more data halls, and (M) is the number of chillers that serve as backup units. Additionally, or alternatively, the chiller plant 202 may include a redundant number of chiller blocks 206, for example, with an N+1 or an N+M redundancy model, where (N) is the number of chiller blocks 206 required to meet the cooling demands of the one or more data halls, and (M) is the number of chiller blocks 206 that serve as backup units. Cooling liquid is supplied to the data hall 204 via a redundant number of cooling fluid supply lines 208.

The chiller plant 202 includes multiple thermal storage tanks 210, such as thermal storage tank 210a and thermal storage tank 210n. A thermal storage tank 210 receives chilled cooling fluid from one or more cooling fluid supply lines 208. The thermal storage tanks 210 provide a ride-through time to allow the chiller plant 202 to continue supplying chilled cooling fluid to the data hall 204 while restarting chillers after a loss of power condition. In one example, the ride-through time provided by one or more thermal storage tanks 210 is from (5) to (10) minutes.

The chiller plant 202 includes multiple buffer tanks 212, such as buffer tank 212a and buffer tank 212n. A buffer tank 212 receives warmed cooling fluid from one or more cooling fluid return lines 214. The cooling fluid return lines 214 return warmed cooling fluid from the data hall 204 to the chiller plant 202. The buffer tanks 212 dampen fluctuations in thermal loads in the warmed cooling fluid received from the data hall 204. Additionally, or alternatively, the buffer tanks 212 provide time for the chiller blocks to ramp up and/or down in response to changes in thermal loads of the warmed cooling fluid. In one example, the buffer tanks receive chilled cooling fluid, for example, from one or more cooling fluid supply lines 208, that is mixed with warmed cooling fluid. The chilled cooling fluid may be mixed with the warmed cooling fluid in the buffer tanks 212, for example, to provide a cooling fluid supply to the chiller blocks 206 that is within a specified temperature range.

The data hall 204 includes a set of liquid-cooled loads 216 and a set of air-cooled loads 218. The data hall 204 includes multiple coolant distribution units (CDUs) 220, such as CDU 220a and CDU 220n. The CDUs 220 pump chilled cooling fluid from the thermal storage tanks 210 to the liquid-cooled loads 216. Additionally, or alternatively, the CDUs 220 may pump warmed cooling fluid from the liquid-cooled loads 216 to the buffer tanks 212. In one example, the CDUs 220 include heat exchangers that extract heat from the warmed cooling fluid flowing through the cooling fluid return lines 214. The data hall 204 may include a redundant number of CDUs 220. The redundant number of CDUs 220 may correspond to an N+1 or an N+M redundancy model, where (N) is the number of CDUs 220 required to meet the cooling demands of the liquid-cooled loads 216, and (M) is the number of CDUs 220 that serve as backup units.

The data hall 204 includes an air distribution fanwall 222 that supplies cooling air to the air-cooled loads 218. The air distribution fanwall 222 includes an array of variable speed fans. The variable speed fans may be arranged in rows to create a uniform “wall” of airflow throughout the data center. The air distribution fanwall 222 may draw intake air from a cooling source. The fans push the chilled air through the data hall 204 to cool the air-cooled loads 218. The chilled air may be pushed through underfloor plenums, ducks, and/or cold aisles to cool the air-cooled loads 218. Outgoing cooling air may be recirculated through a cooling source and/or exhausted.

As shown in FIG. 2, in one example, the liquid-cooled loads 216 represent a subset of the air-cooled loads 218. The liquid-cooled loads 216 include a set of liquid coolable computing devices 224 that are cooled at least in part by cooling liquid supplied by the CDUs 220. The liquid-cooled loads 216 may be cooled additionally by the cooling air supplied by the air distribution fanwall 222. The air-cooled loads 218 include a set of air coolable computing devices 226 that are cooled by cooling air supplied by the air distribution fanwall 222. The air coolable computing devices 226 may include liquid coolable cooling devices that are not presently being cooled by cooling liquid.

The data hall 204 includes multiple liquid cooling loops 228. The liquid cooling loops 228 includes multiple supply loops 230 that supply chilled cooling fluid from the CDUs 220 to the air-cooled loads 218 and multiple return loops 232 that return warmed cooling fluid to the CDUs 220. The supply loops 230 include multiple supply manifolds 234 and multiple return manifolds 236. The supply manifolds 234 and the return manifolds 236 may run in close proximity to the liquid coolable computing devices 224, such as in overhead trays and/or adjacent trays. The liquid coolable computing devices 224 may tie into a nearby supply manifold 234 and a nearby return manifold 236 via feeder lines. The feeder lines may connect to the supply manifold 234 and/or return manifold 236, for example, via quick-connect fittings. Computing devices may be added and/or removed from the liquid-cooled loads 216, for example, via the quick-connect fittings, depending on the colling demands of the computing devices.

In one example, the liquid coolable computing devices 224 includes GPUs and other heat-intensive hardware. Liquid coolable computing devices 224 may include direct-to-chip cooling technology and/or immersion cooling technology. Direct-to-chip cooling technology utilizes cold plats that are attached to the liquid coolable computing device 224 such as to the surface of computing chips of the liquid coolable computing devices 224. The cooling fluid is pumped through the cooling chips, absorbing and transporting heat away from the liquid coolable computing devices 224. Immersion cooling technology involves submerging the liquid coolable computing devices 224 directly into the cooling fluid, where heat generated by the liquid coolable computing devices 224 is absorbed by the cooling fluid surrounding them.

The CDUs 220 are controlled to provide a specified pressure differential of the cooling fluid in the liquid cooling loops 228. The pressure differential of the cooling fluid determines the flow rate of cooling fluid through the liquid cooling loops 228. In one example, the flow rate of cooling fluid is controlled, for example, via pressure differential, to provide from 0.5 to 5 liters per-minute, per kW of rack power. Additionally, or alternatively, the flow of cooling fluid through the liquid cooling loops 228 may be controlled based on the temperature and/or flow rate of the cooling fluid. The temperature and/or flow rate of the cooling fluid may be measured at one or more of the following locations: the supply loops 230, the supply manifolds 234, the return loops 232, or the return manifolds 236. In one example, the temperature and/or flow rate is measured at one or more locations where a liquid coolable computing device 224 connects with a supply manifold 234 and/or return manifold 236. The flow rate of cooling fluid may be controlled for particular liquid coolable computing devices 224 by variable frequency drive (VFD) valves. The VFD valves may be located in a feeder line that ties the liquid coolable computing devices 224 into a supply manifold 234 and/or return manifold 236.

Referring further to FIG. 2, the cooling system infrastructure 200 includes a core network hub chiller plant 238 that supplies cooling fluid to core network hub cooled loads 240.

The core network hub chiller plant 238 may include cooling equipment similar to the equipment described with reference to the data hall chiller plant 202. The core network hub cooled loads 240 may be cooled via equipment similar to the equipment described with respect to data hall 204. Additionally, or alternatively, the cooling system infrastructure 200 may include cooling towers, economizers, and/or evaporative coolers that provide heat transfer for the data hall chiller plant 202 and/or the core network hub chiller plant 238.

### Modular Cooling System Infrastructure

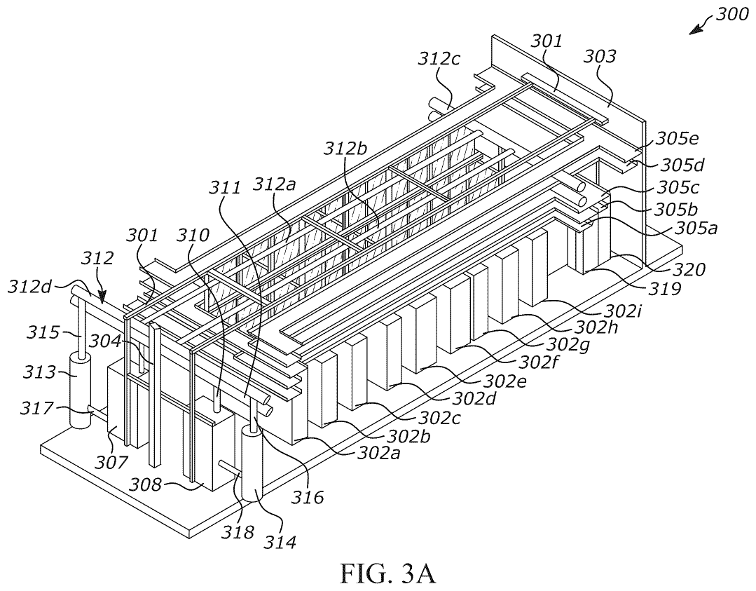

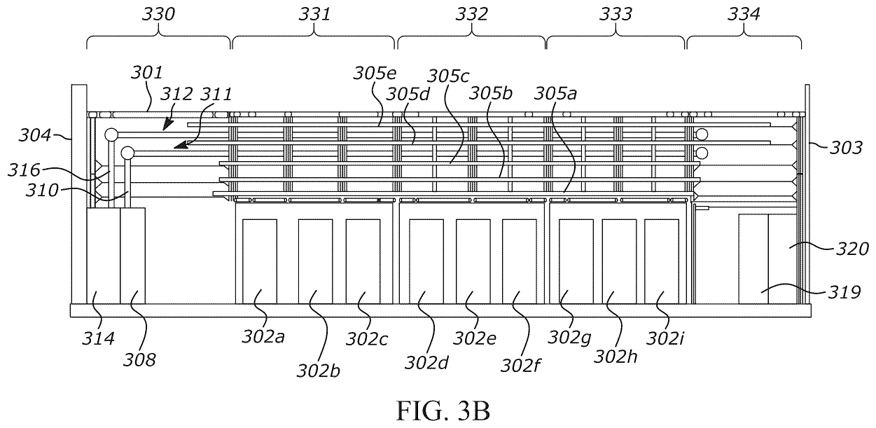

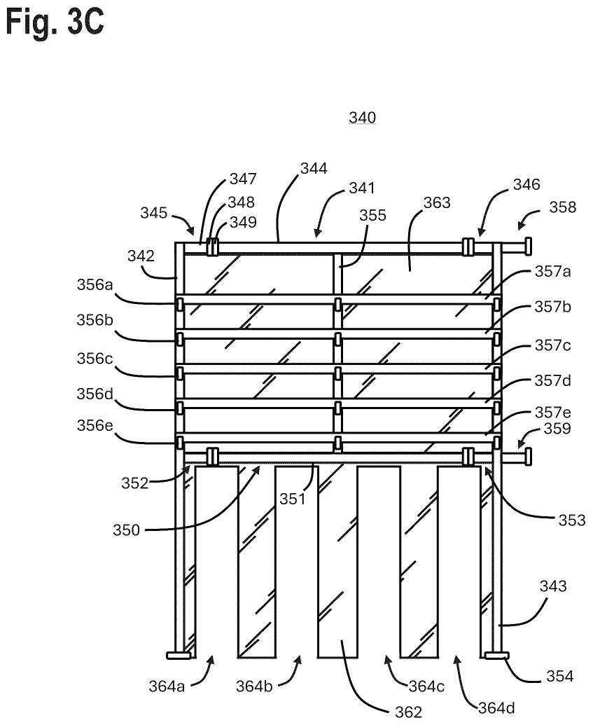

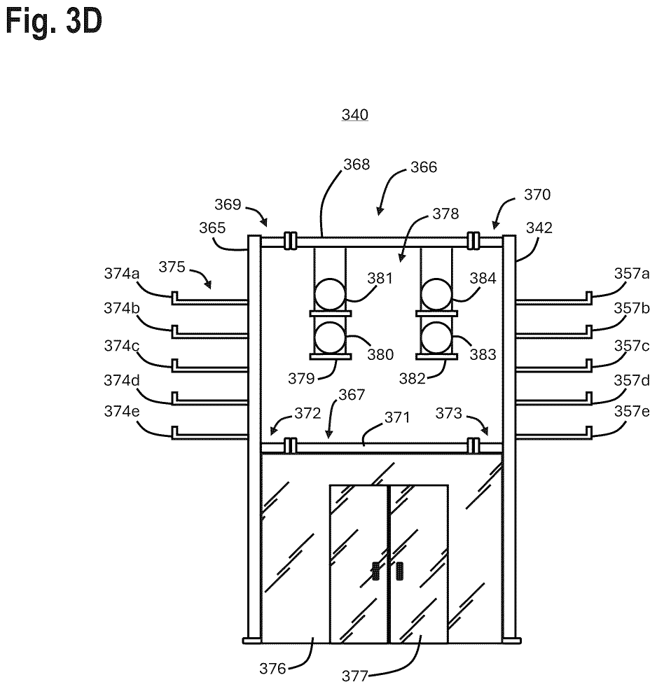

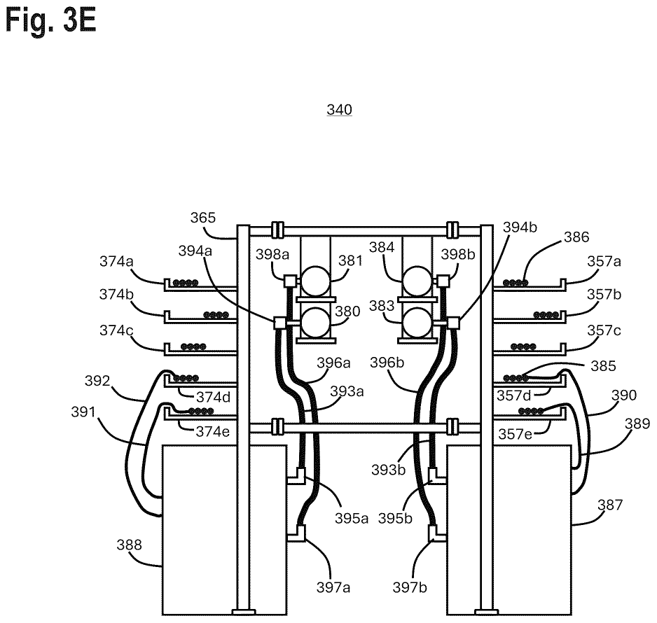

FIG. 3A illustrates a data center pod architecture 300, referred to herein as a data center pod 300. The data center pod 300 includes a support frame 301 and racks 302a-302i. The frame 301 is supported between a wall 303 of the data center and a support beam 304. The racks 302a-302i may store computing devices, such as servers and switches, that generate heat. The data center pod 300 includes containers 305a-305e, such as trays, for holding cables to connect to the computing devices stored in the racks 302a-302i. The containers 305a-305e are supported by support members (not shown in this figure). In an embodiment, containers 305a-305c run communications cabling to and from the racks 302a-302i. The containers 305d and 305e may run power cables to and from the racks 302a-302i.

Cooling units 307 and 308 receive a flow of heated coolant liquid, cool the heated coolant liquid, and release the cooled coolant liquid to cool liquid-cooled loads, such as computing devices, in the racks 302a-302i. A cooling system includes a coolant pipe assembly. The coolant pipe assembly includes an egress pipe 310 to direct the flow of the coolant liquid from the cooling unit 308 to a crosswise portion of a coolant supply pipe 311. In the example embodiment illustrated in FIG. 3A, the coolant supply pipe 311 is configured as a loop. For purposes of illustration, the loop structure of the coolant supply pipe 311 is not visible in FIG. 3A. However, the loop structure is illustrated in FIGS. 2, 4, and 6. The cooling unit 308 directs coolant liquid into the coolant supply pipe 311 at one position along the loop, and the cooling unit 307 directs coolant liquid into the coolant supply pipe 311 at another position along the loop.

A coolant return pipe 312 carries the coolant liquid that has been heated by the liquid-cooled loads stored in the racks 302a-302i toward the cooling units 307 and 308. The coolant return pipe 312 includes lengthwise segments 312a and 312b and crosswise segments 312c and 312d. As illustrated in FIG. 6 below, crosswise segments 312c and 312d may connect with crosswise segments of adjacent pods to allow fluid flow between adjacent pods in a data center.

The system includes buffer tanks 313 and 314 along a liquid flow path between the coolant return pipe 312 and the cooling units 307 and 308, respectively. A connector pipe 315 connects the crosswise segment 312d of the coolant return pipe 312 to the buffer tank 313. A connector pipe 316 connects the crosswise segment 312d of the coolant return pipe 312 to the buffer tank 314. A connector pipe 317 connects the buffer tank 313 to the cooling unit 307. A connector pipe 318 connects the buffer tank 314 to the cooling unit 308.

The buffer tank 314 stores a reservoir of coolant liquid. As the buffer tank 314 receives heated coolant liquid from the coolant return pipe 312, the heated coolant liquid mixes with the reservoir of coolant liquid prior to flowing toward the cooling unit 308.

The data center pod 300 includes power units 319 and 320. The power units 319 and 320 may be implemented as an RPPS. The RPPS provides power to server racks and network equipment from a centralized location. In one or more embodiments, cabling is connected from the power units 319 and 320 to the racks 302a-302i via the containers 305d or 305e.

The data center pod 300 is made up of interconnectable modules. Each module includes a support frame, a storage compartment for storing a computing device, and a cable support segment. In some embodiments, each module includes a cooling pipe segment and an exhaust pipe segment. In some embodiments, each module includes at least one valve element connected to a pipe segment. For example, a module may include a valve at one end of the cooling pipe segment and a valve at one end of the exhaust pipe segment. In this manner, connecting two segments together results in a valve pair capable of isolating a module from coolant flowing through a coolant and/or exhaust pipe.

Modules may be fabricated with the frame components, cable support segments, and pipe segments. Fabricated modules may be installed by connecting pipe segments and connecting cable support segments.

FIG. 3B illustrates a side view of the data center pod 300. The data center pod 300 includes five modules: a cooling module 330, interconnectable data modules 331, 332, and 333, and a power module 334. In one or more embodiments, the modules 330-334 are independently configurable according to data center constraints. For example, one data center may be fabricated with a single data module. Another data center may be fabricated with five side-by-side data modules. Another data center may be fabricated with three side-by-side data modules, as illustrated in FIG. 3B.

FIG. 3C illustrates an interconnectable data module 340. The interconnectable data module 340 may correspond, for example, to the interconnectable data module 331 illustrated in FIG. 3B. The interconnectable data module 340 includes a top frame member 341, a first side frame member 342, and a second side frame member 343. The top frame member 341 includes a center horizontal frame member 344 and connectors 345 and 346. Connector 345 includes a horizontal section 347 and a connector plate 348. The connector plate 348 connects to a connector plate 349 at the end of the center horizontal frame member 344 to form the top frame member 341. In an example embodiment, the center horizontal frame member 344 and the horizontal section 347 of the connector 345 are I beams. The connector plate 348 is a vertical plate affixed to the end of the I beam such as by welding. The connector plate 348 is attached to the connector plate 349, such as by welding, bolts, rivets, or by a mechanical attachment mechanism. The interconnectable data module 340 includes a middle horizontal frame member 350. The middle horizontal frame member 350 includes a center frame member 351 and connectors 352 and 353. The interconnectable data module 340 includes connectors 354 to attach the side frame members 342 and 343 to the ground. The connector 354 may include a horizontal plate. The connector 354 may be attached to the ground by bolts, pins, or nails, for example.

The interconnectable data module 340 includes a vertical support frame member 355 extending between the top frame member 341 and the middle horizontal frame member 350. Container support members 356a, 356b, 356c, 356d, and 356e are attached to the side frame members 342 and 343 and the vertical support frame member 355. The support members 356a-356e are numbered only for the first side frame member 342 in FIG. 3C for purposes of clarity in description. The support members 356a-356e support containers 357a, 357b, 357c, 357d, and 357e. The containers 357a-357e extend horizontally between the side frame members 342 and 343, supported by the support members 356a-356e. In an alternative embodiment, the containers 357a-357e are mounted directly to the side frame members 342 and 343 and the vertical support frame member 355. The containers 357a-357e are configured to support wiring and cabling running along a side of the data center pod 300. The containers 357a-357e may be made of plastic or metal and may be formed as solid sheets or as a mesh structure.

The interconnectable data module 340 includes connectors 358 and 359 for connecting with adjacent horizontal frame members to form an adjacent interconnectable data module. For example, an adjacent horizontal frame member may be connected between the connector 358 and a distal connector of a distal side frame member. An adjacent center frame member 351 may be connected between the connector 359 and a distal connector of the distal side frame member. A data center pod is fabricated with any number of side-by-side interconnectable modules by repeatedly connecting horizontal frame members to side frame member connectors. The first side frame member 342 may not include a connector for connecting to a leftward module when viewed from the perspective of FIG. 3C. Instead, end modules, such as a cooling unit module and a power module, may include frame members that connect inner module frame members to end supports, such as vertical I beams and walls.

The interconnectable data module 340 includes panels 362 and 363. The panels 362 and 363 may be made of plastic or other polymers. The panel 362 includes openings 364a, 364b, 364c, and 364d. In operation, server racks are installed in the openings 364a-364d. The panels 362 and 363 as well as additional panels included in additional interconnectable modules define a first environment on one side of the panels and a second environment on the other side of the panels. In particular, a center aisle of the data center pod 300 may be enclosed by the panels of the modules in the pod 300. A data center temperature management system, such as the temperature monitoring and control module 121 illustrated in FIG. 1, may control the temperature within the first environment defined by the enclosed center aisle of the pod 300. The data center temperature management system may maintain a temperature in the second environment to be different from a temperature in the first environment.

FIG. 3D illustrates a side view of the interconnectable data module 340 with support containers that are mounted directly to the frame members. The interconnectable data module 340 includes the first side frame member 342 and a third side frame member 365. The first side frame member 342 and the third side frame member 365 are connected by a top frame member 366 and a middle horizontal frame member 367. The top frame member 366 includes a center frame member 368 and connectors 369 and 370. The middle horizontal frame member 367 includes a center frame member 371 and connectors 372 and 373. The containers 357a-357e are mounted to the first side frame member 342. Another set of containers 374a, 374b, 374c, 374d, and 374e are mounted to the third side frame member 365. In an example embodiment, the containers are shaped to define a cavity 375. When a set of modules is interconnected side-by-side, the containers of the respective modules are attached end-to-end. Accordingly, the cavity extends along the length of the attached containers. In addition, containers may be mounted at one or both ends of the pod 300 to form a contiguous cavity 375 around the interconnectable data modules 331, 332, and 333 of the pod 300.

A panel 376 is mounted between the first side frame member 342, the third side frame member 365, the middle horizontal frame member 367 and the ground. A door 377 is located in the panel 376 to allow access to an aisle space between the first side frame member 342 and the third side frame member 365. The interconnectable data module 340 also includes an upper panel (not shown) between the first side frame member 342, the third side frame member 365, the middle horizontal frame member 367 and the top frame member 366. This panel is not shown, for purposes of description, to provide a view into an upper region 378 of the aisle space between the first side frame member 342 and the third side frame member 365. A liquid cooling pipe support member 379 is supported by the top frame member 366. The liquid cooling pipe support member 379 supports a first coolant supply pipe segment 380 and a first coolant return pipe segment 381. Liquid cooling pipe support member 382 is also supported by the top frame member 366. The liquid cooling pipe support member 382 supports a second coolant supply pipe segment 383 and a second coolant return pipe segment 384. The first coolant supply pipe segment 380 and the second coolant supply pipe segment 383 are lengthwise segments of a loop-shaped configuration of the coolant pipe. The first coolant return pipe segment 381 and the second coolant return pipe segment 384 are lengthwise segments of a loop-shaped configuration of the coolant return pipe. In an embodiment, the upper panel (not shown) between the first side frame member 342, the third side frame member 365, the middle horizontal frame member 367, and the top frame member 366 define holes to allow the first coolant supply pipe segment 380, the first coolant return pipe segment 381, the second coolant supply pipe segment 383, and the second coolant return pipe segment 384 to extend through the upper panel (not shown).

FIG. 3E illustrates the side view of the interconnectable data module 340 with data transmission lines, coolant supply pipes, and coolant return pipes connected to racks such as the racks 302a-302i illustrated in FIG. 3A.

FIG. 3E illustrates data transmission cables 385 supported in containers 357c, 357d, 357e, 374c, 374d, and 374e. Power cables 386 are supported in containers 357a, 357b, 374a, and 374b. For example, the power cables 386 may connect a power unit 319 illustrated in FIG. 3A to a server mounted in a rack 387. The rack 387 may correspond to the rack 302a illustrated in FIG. 3A. A rack 388 is positioned in the portion of the interconnectable data module 340 adjacent to the third side frame member 365. Data transmission line 389 extends from the container 357e to the rack 387. Data transmission line 390 extends from the container 357d to the rack 387. Data transmission line 391 extends from the container 374e to the rack 388. Data transmission line 392 extends from the container 374d to the rack 388. While two data transmission lines are illustrated extending from containers to a rack in FIG. 3E for purposes of description, embodiments encompass any number of data transmission lines supported by containers and running to racks in the data center pod 300. For example, a rack may store from one server to dozens of servers. A server may be connected to two power cables for redundancy and between one and four network cables for redundancy, parallel data transmission, intra-rack connections, and intra-module connections.

Coolant supply pipe 393a extends between connector 394a and connector 395a to form a liquid-tight conduit for coolant liquid, such as water, to flow from the first coolant supply pipe segment 380 to the rack 388. Coolant supply pipe 393b extends between connector 394b and connector 395b to form a liquid-tight conduit for coolant liquid, such as water, to flow from the second coolant supply pipe segment 383 to the rack 387. Coolant return pipe 396a extends between connector 397a and connector 398a to form a liquid-tight conduit for heated coolant liquid, such as heated water, to flow from the rack 388 to the first coolant return pipe segment 381. Coolant return pipe 396b extends between connector 397b and connector 398b to form a liquid-tight conduit for heated coolant liquid, such as heated water, to flow from the rack 387 to the second coolant return pipe segment 384.

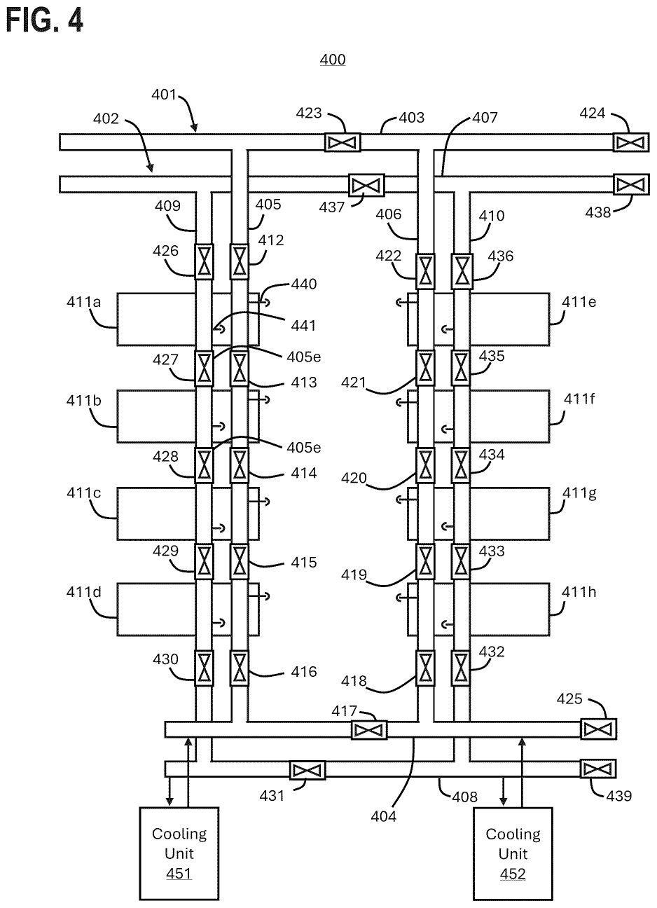

FIG. 4 illustrates modular data center pod cooling system 400 in accordance with one or more embodiments. The modular data center pod cooling system 400 includes a coolant supply pipe network 401 and a coolant return pipe network 402. The coolant supply pipe network includes a first end pipe 403, a second end pipe 404, a first side pipe segment 405, and a second side pipe segment 406. The coolant return pipe network includes a first end pipe 407, a second end pipe 408, a first side pipe segment 409, and a second side pipe segment 410. The first side pipe segment 405 may correspond to the first coolant supply pipe segment 380 illustrated in FIG. 3D. The second side pipe segment 406 may correspond to the second coolant supply pipe segment 383 in FIG. 3D. The first side pipe segment 409 may correspond to the first coolant return pipe segment 381 illustrated in FIG. 3D. The second side pipe segment 410 may correspond to the second coolant return pipe segment 384 in FIG. 3D.

Cooling unit 451 supplies cooling liquid to the coolant supply pipe network 401 and receives heated exhaust coolant from the coolant return pipe network 402. Cooling unit 452 supplies cooling liquid to the coolant supply pipe network 401 and receives heated exhaust coolant from the coolant return pipe network 402. While FIG. 4 illustrates a modular data center pod cooling system that includes two cooling units, embodiments encompass any number of cooling units, including one cooling unit.

Racks 411a, 411b, 411c, 411d, 411e, 411f, 411g, and 411h receive coolant from the coolant supply pipe network 401, heat the coolant by running the coolant over liquid-cooled loads, such as heat-generating processors and other computing components, and direct the heated coolant to the coolant return pipe network 402.

The liquid cooling system includes valves 412-439. Valve 412 is located along the first side pipe segment 405 of the coolant supply pipe network 401 at the end of the row of racks 411a-411d. Valve 413 is located along the first side pipe segment 405 on an opposite side of the connector 440 from valve 412. The connector 440 provides coolant from the first side pipe segment 405 to the rack 411a. For example, the connector 440 may correspond to the connector 394a illustrated in FIG. 3E. Closing valves 412 and 413 isolates the connector 440 from coolant flow in the coolant supply pipe network 401. Valve 426 is located along the first side pipe segment 409 of the coolant return pipe network 402 at the end of the row of racks 411a-411d. Valve 427 is located along the first side pipe segment 409 on an opposite side of the connector 441 from valve 426. The connector 441 provides heated exhaust coolant from the rack 411a to the first side pipe segment 409. For example, the connector 441 may correspond to the connector 398a illustrated in FIG. 3E. Closing valves 426 and 427 isolates the connector 441 from liquid exhaust flow in the coolant return pipe network 402.

Valves 414-416 and 418-422 are similarly located along the coolant supply pipe network 401 on opposing sides of connectors to racks 411b-411h to selectively allow liquid flow to and from the racks 411b-411h or to isolate the racks 411b-411h from fluid flow in the coolant supply pipe network 401. Valves 427-430 and 432-436 are similarly located along the coolant return pipe network 402 on opposing sides of connectors to racks 411b-411h to selectively allow liquid flow from the racks 411b-411h or to isolate the racks 411b-411h from fluid flow in the coolant return pipe network 402.

Valves 417 and 423 are located along the second end pipe 404 and the first end pipe 403, respectively. Valves 431 and 437 are located along the second end pipe 408 and the first end pipe 407, respectively. Closing valves 417, 423, 431, and 437 isolates one row of racks 411a-411d from the other row of racks 411e-411h in a data center pod. When valves 417, 423, 431, and 437 are closed, the cooling unit 451 supplies cooling liquid to racks 411a-411d, and the cooling unit 452 is prevented from supplying cooling liquid to racks 411a-411d. Likewise, when valves 417, 423, 431, and 437 are closed, the cooling unit 452 supplies cooling liquid to racks 411e-411h, and the cooling unit 451 is prevented from supplying cooling liquid to racks 411e-411h.

Valves 424, 425, 438, and 439 are located along the first and second end pipes of the coolant supply pipe network 401 and the coolant return pipe network 402 to selectively connect the coolant supply pipe network 401 and the coolant return pipe network 402 to pipe networks of an adjacent data center pod. The adjacent data center pod includes cooling units for supplying cooled coolant, such as water, to racks. When valves 424, 425, 438, and 439 are open, liquid is permitted to flow between adjacent pods, allowing the cooling units of one pod to take on a portion of a cooling load of an adjacent pod.

The loop-shaped coolant and coolant return pipe systems in combination with the positioning of valves on either side of coolant supply connectors and coolant return connectors, that are connected to the racks illustrated in FIG. 4, allow for the selective isolation of racks from a liquid cooling system while continuing to provide access to adjacent racks. For example, in normal operation, coolant liquid flows to the rack 411c from the cooling unit 451 via the second end pipe 404, the valve 416, and the valve 415. If an event is detected in rack 411d that requires disconnection from the cooling system, valves 415, 416, 429, and 430 are closed. However, due to the loop configuration of the coolant system, coolant continues to flow to rack 411c via a new liquid flow path. Cooling units 451 and 452 supply coolant to rack 411c via the second end pipe 408, the second side pipe segment 406, the first end pipe 403, and the first side pipe segment 405 via open valves 412, 413, and 414.

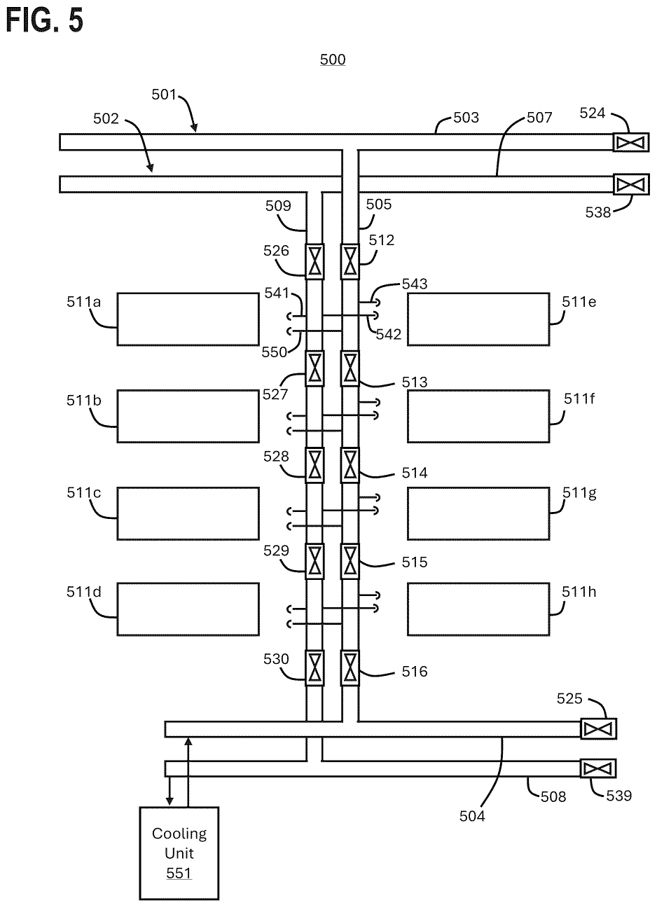

FIG. 5 illustrates an interconnectable data center pod cooling system 500 in accordance with an embodiment. The interconnectable data center pod cooling system 500 includes a coolant supply pipe network 501 and a coolant return pipe network 502. The coolant supply pipe network includes a first end pipe 503, a second end pipe 504, and a pipe segment 505 that extends between the first end pipe 503 and the second end pipe 504. The coolant return pipe network 502 includes a first end pipe 507, a second end pipe 508, and a pipe segment 509 that extends between the first end pipe 507 and the second end pipe 508.

Cooling unit 551 supplies cooling liquid to the coolant supply pipe network 501 and receives heated exhaust coolant from the coolant return pipe network 502.

Racks 511a, 511b, 511c, and 511d receive coolant from the coolant supply pipe network 501, heat the coolant by running the coolant over liquid-cooled loads, such as heat-generating processors and other computing components, and direct the heated coolant to the coolant return pipe network 502.

The liquid cooling system includes valves 512-516, 524, 525-530, 538, and 539. Valve 512 is located along the pipe segment 505 of the coolant supply pipe network 501 at the end of the row of racks 511a-511d. Valve 513 is located along the pipe segment 505 on an opposite side of the connectors 540 and 542 from valve 513. The connector 540 provides coolant from the pipe segment 505 to the rack 511a. The connector 542 provides coolant from the pipe segment 505 to the rack 511e. Closing valves 512 and 513 isolates the connectors 540 and 542 from coolant flow in the coolant supply pipe network 501. Valve 526 is located along the pipe segment 509 of the coolant return pipe network 502 at the end of the row of racks 511a-511d. Valve 527 is located along the pipe segment 509 on an opposite side of the connectors 541 and 543 from valve 527. The connector 541 provides heated exhaust coolant from the rack 511a to the pipe segment 509. The connector 543 provides heated exhaust coolant from the rack 511e to the pipe segment 509. Closing valves 526 and 527 isolates the connectors 541 and 543 from heated exhaust coolant flow in the coolant return pipe network 502.

Valves 514-516 are similarly located along the coolant supply pipe network 501 on opposing sides of connectors to racks 511b-511d and 511f-511h to selectively allow liquid flow to and from the racks or to isolate the racks from fluid flow in the coolant supply pipe network 501. Valves 527-530 are similarly located along the coolant return pipe network 502 on opposing sides of connectors to racks 511b-511d and 511f-511h to selectively allow liquid flow from the racks or to isolate the racks from fluid flow in the coolant return pipe network 502.

Valves 524, 525, 538, and 539 are located along the first and second end pipes of the coolant supply pipe network 501 and the coolant return pipe network 502 to selectively connect the coolant supply pipe network 501 and the coolant return pipe network 502 to pipe networks of an adjacent data center pod. The adjacent data center pod includes cooling units for supplying cooled coolant, such as water, to racks. When valves 524, 525, 538, and 539 are open, liquid is permitted to flow between adjacent pods, allowing the cooling units of one pod to take on a portion of a cooling load of an adjacent pod.

Opening valves 524, 525, 538, and 539 to allow liquid flow between adjacent data center pod cooling systems allows for the selective isolation of racks from coolant liquid supplied by the cooling system while continuing to provide access to adjacent racks. For example, in normal operation, coolant liquid flows to the racks 511a and 511e from the cooling unit 511 via the second end pipe 504 and through the valves 516, 515, 514, and 513. If an event is detected in rack 511d that requires disconnection from the cooling system, valves 515, 516, 529, and 530 are closed, thereby isolating racks 511d and 511h from fluid flow between the racks and the cooling system. If the valves 524, 538, 525, and 539 are closed, racks 511a-511c and 511e-511g are also isolated from fluid flow between the racks and the cooling system. However, if valves 524 and 538 are open, allowing fluid flow between the data center pod cooling system 500 and an adjacent data center pod cooling system, cooling fluid continues to flow to the racks 511a-511c and 511e-511g via the first end pipe 503.

FIG. 6 illustrates an interconnectable data center pod cooling system 600 in accordance with an embodiment. The system 600 includes interconnectable data center pod cooling systems 601a, 601b, . . . 601n. As described herein, the term interconnectable refers to cooling systems that are physically connected by valves 603a, 603b, 603c, . . . 603n, and where opening the valves 603a, 603b, 603c, . . . 603n corresponds to “connecting” the separate pod cooling systems by allowing coolant liquid to flow between the separate pod cooling systems. In other words, the cooling systems remain physically connected by valves, but selectively connect coolant flows within and between the cooling systems by opening and closing the valves of the cooling systems. In an example, the interconnectable data center pod cooling systems 601a, 601b, . . . 601n correspond to the system 400 illustrated in FIG. 4 or the system 500 illustrated in FIG. 5. For example, valves 603b may correspond to valves 424, 438, 425, and 439 in FIG. 4. Alternatively, valves 603b may correspond to valves 524, 538, 525, and 539 in FIG. 5.

Data center pod cooling system 601a provides coolant liquid to racks 602a-602n. Cooling unit 604a circulates the coolant liquid by receiving heated exhaust coolant from a coolant return pipe system, cooling the heated exhaust coolant, and supplying cooled coolant liquid to a coolant supply pipe system. Similarly, cooling unit 604b circulates the coolant liquid to cool racks 605a, 605b, . . . 605n. Cooling unit 604n circulates coolant liquid to cool racks connected to interconnectable data center pod cooling system 601n.

Controller 653 is communicatively connected to valves 603a, 603b, . . . 603n to selectively open and close the valves. In addition, in an embodiment where interconnectable data center pod cooling systems 601a, 601b, . . . 601n correspond to the system 400 illustrated in FIG. 4, the controller 653 is communicatively connected to valves 412-439 to selectively open and close the valves. As used herein, the term communicatively coupled refers to a data communication line or wireless communication mechanisms, including transmitters and receivers. The controller 653 generates command signals to open and close valves. In some embodiments, the controller 653 generates command signals to partially open or close valves to modify a rate of liquid flow through the valves. The controller 653 includes one or more processors and computing logic and may incorporate computing elements of the temperature monitoring and control module 121 described in FIG. 1.

### 3. Connecting and Isolating Components in Modular Cooling System

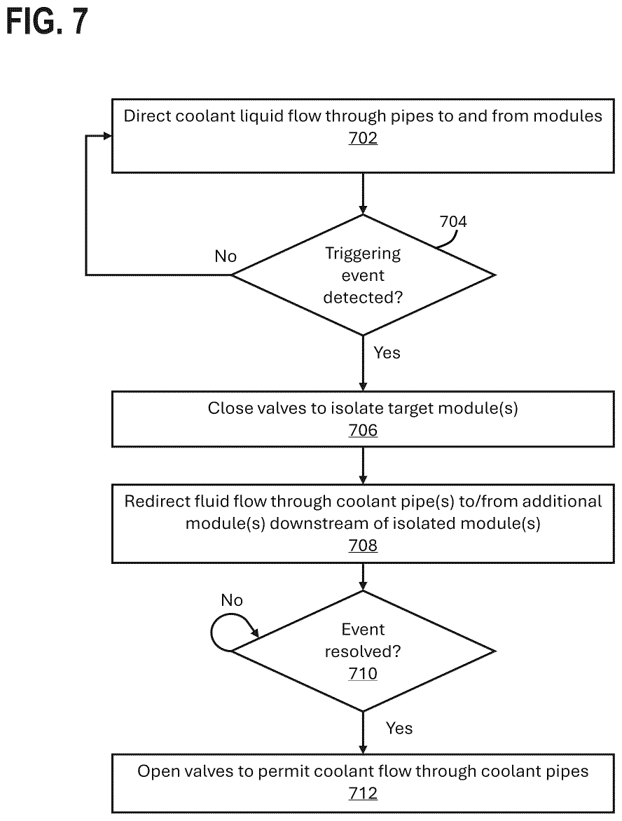

FIG. 7 illustrates an example set of operations for selectively connecting and isolating components in a modular cooling system in accordance with one or more embodiments. One or more operations illustrated in FIG. 7 may be modified, rearranged, or omitted. Accordingly, the particular sequence of operations illustrated in FIG. 7 should not be construed as limiting the scope of one or more embodiments.

A system directs coolant liquid through a coolant supply pipe and a coolant return pipe to direct coolant liquid to and from racks in an interconnectable data center pod (Operation 702). The interconnectable data center pod includes a support frame for supporting coolant supply pipes, communications cables, and power cables. Racks are arranged in rows along the length of the data center pod. The communications cables, power cables, and coolant supply pipes are connected to the racks. For example, network cables and power cords may be connected to servers mounted in the racks. Tubes may extend from connectors in coolant supply pipes supported by the frame to connectors in the racks. The connectors in the racks may be connected to cooling elements that distribute cooling liquid over the surface of electronic components, such as processors and direct heated coolant from the electronic components to a heated exhaust coolant connector. The heated exhaust coolant connector connects to a coolant return pipe supported by the frame via a connecting tube.

In some embodiments, a data center pod includes sets of interconnected modules. Each module includes a frame defining a rack storage compartment and a set of cable support segments. The frame may define one rack storage compartment on one side of an aisle and another rack storage compartment on an opposite side of the aisle. The frame may include support members to support pipe segments of a data center pod cooling system. Connecting the pipe segments of multiple modules forms a fluid-tight coolant supply pipe and a fluid-tight coolant return pipe. The fluid-tight coolant supply pipe is configured to direct coolant liquid to computing components stored in the compartments. The fluid-tight coolant return pipe is configured to direct heated cooling liquid away from the computing units in the compartments.

The modules may include valves to manage liquid flow through the pipe segments. Additionally, or alternatively, valves may be located between modules to manage liquid flow into, and out from, pipe segments. The pipes may be configured in a loop shape. Liquid may flow in different directions through different portions of the loop. For example, coolant liquid may flow in a clockwise direction through one portion of the loop and in a counter-clockwise direction through another portion of the loop. The loop configuration of the coolant supply pipes acts as a manifold for distributing coolant from a coolant pipe to racks in a data center pod. The loop configuration of coolant return pipes acts as a manifold to receive heated exhaust coolant from the racks in the data center pod.

The system determines if a triggering event is detected associated with one or more target racks (Operation 704). A triggering event may include, for example, a notification that a leak exists in a rack, a notification that a server mounted in a rack requires replacement or repair, or instructions to performing testing of the isolation capabilities of the system.

Based on detecting the triggering event, the system closes a set of valves to isolate one or more target racks form liquid flowing through the pipes (Operation 706). In the embodiment where a coolant supply pipe is configured in a loop shape, closing a valve along the coolant supply pipe stops liquid flow from one direction through the pipe. However, due to the loop shape, liquid may flow through the pipe toward the valve from the opposite direction. Accordingly, in an embodiment, the system closes a pair of valves to isolate a target rack. One valve is located along a coolant supply pipe on one side of a connector that connects the coolant supply pipe to the target rack. Another valve is located along the coolant supply pipe at the opposite side of the connector. Accordingly, closing the valves isolates the connector from coolant liquid flow through the coolant supply pipe. Similarly, the system may close a pair of valves along a coolant return pipe to prevent the flow of exhaust coolant liquid to and from the isolated rack.

Based on closing the valves, coolant liquid flow is redirected through coolant supply pipes and coolant return pipes to provide coolant liquid to one or more non-isolated racks (Operation 708). For example, when a valve is open, coolant liquid may flow along a portion of a coolant supply pipe in a first direction. When a pair of valves is closed to isolate a target rack along the portion of the coolant supply pipe, the loop configuration of the coolant supply pipe allows coolant liquid to flow along the portion of the coolant supply pipe from the opposite direction. Accordingly, the system may continue to supply coolant liquid to, and direct heated coolant liquid from, non-isolated racks along the portion of the coolant supply pipe that includes an isolated rack that is isolated from the coolant liquid by closing the valves.

In one or more embodiments, the closing of the valves to isolate one or more target racks results in the redirecting of coolant liquid in a different direction through a coolant supply or coolant return pipe without requiring a change in operation of pumps, cooling units, or additional valves (e.g., valves that were not used to isolate the target module(s)). Instead, the loop-shaped structure of the coolant supply pipe and the coolant return pipe results in the redirection of the coolant liquid to non-isolated modules.

In an embodiment, a liquid cooling system does not include a loop shape in a data center pod, or both sides of a loop shape may need to have valves closed to isolate one or more racks from a coolant liquid flow. In such an embodiment, the system may still allow coolant liquid to flow to non-isolated racks by opening valves to adjacent data center pods. Multiple data center pods may be connected by valves. The data center pods include independent cooling units. If a cooling system of a data center pod does not include a loop shape, or if both sides of a loop have closed valves that inhibits coolant liquid flow to one or more downstream racks, opening valves connecting the data center pod to an adjacent data center pod allows coolant liquid flow between the data center pod and the adjacent data center pod.

For example, referring to FIG. 5, valves 515, 516, 529, and 530 may be closed, isolating racks 511d and 511h. However, racks 511a-511c and 511e-511g may also be isolated since coolant liquid is unable to flow from the cooling unit 511 to the racks 511a-511c and 511e to 511g. Opening valves 524 and 538 allows coolant liquid flow between the data center pod cooling system 500 and the cooling system of the adjacent pod. As a result, racks 511a-511c and 511e-511g may continue to be cooled by circulating coolant from the adjacent data center pod.

The system determines if the triggering event is resolved (Operation 710). For example, an operator may close a support ticket or enter a notification that a computing device has been repaired or replaced. According to an embodiment, repairing or replacing a computing device may include performing operational tests on the computing device to ensure proper operation of the device. As operators and/or applications are performing the repair or replacement and testing, the loop-shaped structure of the coolant supply and coolant return pipes may continue to direct the flow of coolant liquid to, and from, other racks in a data center pod that are not isolated by valve closures.

Based on determining the triggering event is resolved, the system re-opens the valves to permit coolant liquid to flow through the coolant supply pipes to, and from, the target rack(s) (Operation 712). In an embodiment where a coolant supply pipe is configured in a loop shape, allowing the coolant liquid to flow through the coolant supply pipe to the target module(s) may include reversing a direction of flow of the coolant liquid though the coolant supply pipe. For example, prior to closing the valves in Operation 706, the coolant liquid may flow from a first end of a portion of coolant supply pipe to a second end to supply coolant liquid to modules along a portion of the coolant supply pipe. Upon closing the valves in Operation 706, the coolant liquid may flow from the second end toward the valves to supply coolant liquid to non-isolated modules. Upon re-opening the valves in Operation 712, the coolant liquid may flow from the first end toward the second end to supply the coolant liquid to the modules along the portion of the coolant supply pipe.

While FIG. 7 describes an embodiment where a triggering event triggers the closing of valves, one or more embodiments include a triggering event that triggers the opening of valves. For example, the temperature monitoring and control module 121 of FIG. 1 may determine from sensor data 135 obtained from temperature sensors 115 that a temperature of a cooling liquid in a data center pod cooling system, such as the cooling system 601a illustrated in FIG. 6, exceeds a threshold temperature. The temperature monitoring and control module 121 may include the controller 653. The controller 653 may generate control signals to open valves 603b between the data center pod cooling system 601a and the data center pod 601b. Opening the valves 603b allows cooler coolant liquid from the data center pod 601b to mix with the warmer coolant liquid from data center pod cooling system 601a, thereby cooling the coolant liquid in data center pod cooling system 601a.

As another example, the data center management platform 120 of FIG. 1 may determine that the cooling unit 604a requires servicing or replacement. Accordingly, the controller 653 generates control signals to close valves in the data center pod cooling system 601a to isolate the cooling unit 604a and opens valves 603b to allow coolant liquid flow between the interconnectable data center pod cooling system 601b and the interconnectable data center pod cooling system 601a to provide coolant liquid to racks 602a-602n.

### 4. Computer System

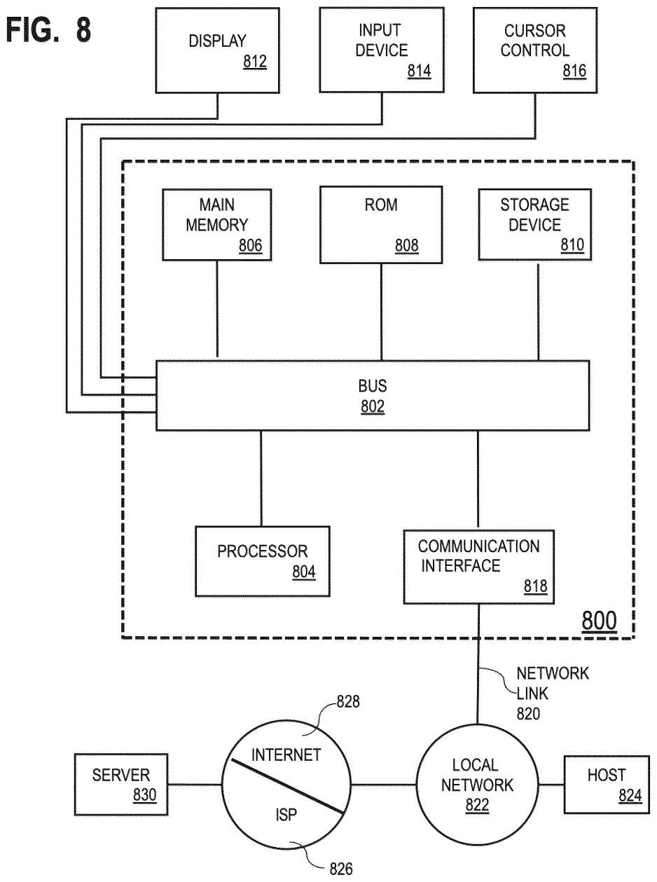

FIG. 8 illustrates an example computer system 800. An embodiment of the disclosure may be implemented upon the computer system 800. As shown in FIG. 8, computer system 800 includes a processing unit 804 that communicates with peripheral subsystems via a bus subsystem 802. These peripheral subsystems may include a processing acceleration unit 806, an I/O subsystem 808, a storage subsystem 818, and a communications subsystem 824. Storage subsystem 818 includes tangible computer-readable storage media 822, computer-readable storage reader 820 and a system memory 810.

Bus subsystem 802 provides a mechanism for letting the various components and subsystems of computer system 800 to communicate with other components and subsystems as intended. Although bus subsystem 802 is shown schematically as a single bus, alternative embodiments of the bus subsystem may utilize multiple buses. Bus subsystem 802 may be any of several types of bus structures, including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus. Additionally, such architectures may be implemented as a Mezzanine bus manufactured to the Institute of Electrical and Electronics Engineers (IEEE) P1386.1 standard.

Processing unit 804 controls the operation of computer system 800. Processing unit 804 can be implemented as one or more integrated circuits (e.g., a conventional microprocessor or microcontroller). One or more processors may be implemented in processing unit 804. These processors may include single core or multicore processors. In certain embodiments, processing unit 804 may be implemented as one or more independent sub processing units 832 and/or 834 with single or multicore processors implemented in one or more processing units. In other embodiments, processing unit 804 may also be implemented as a quad-core processing unit formed by integrating two dual-core processors into a single chip.

In various embodiments, processing unit 804 can execute a variety of programs in response to program code and can maintain multiple concurrently executing programs or processes. At any given time, the program code to be executed can be wholly or partially implemented in processing unit 804 and/or in storage subsystem 818. Through suitable programming, processing unit 804 can provide various functionalities described above. Computer system 800 may additionally include a processing acceleration unit 806 that can include a digital signal processor (DSP), a special-purpose processor, and/or the like.

I/O subsystem 808 may include user interface input devices and user interface output devices. User interface input devices may include a keyboard, pointing devices, such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices, such as the Microsoft Kinect® motion sensor that enables users to control and interact with an input device, such as the Microsoft Xbox® 360 game controller, through a natural user interface using gestures and spoken commands. User interface input devices may also include eye gesture recognition devices, such as the Google Glass® blink detector, that detects eye activity (e.g., ‘blinking’ while taking pictures and/or making a menu selection) from users and transforms the eye gestures as input into an input device (e.g., Google Glass®). Additionally, user interface input devices may include voice recognition sensing devices that enable users to interact with voice recognition systems (e.g., Siri® navigator), through voice commands.

User interface input devices may also include, without limitation, three dimensional (3D) mice, joysticks or pointing sticks, gamepads and graphic tablets, and audio/visual devices, such as speakers, digital cameras, digital camcorders, portable media players, webcams, image scanners, fingerprint scanners, barcode reader 3D scanners, 3D printers, laser rangefinders, and eye gaze tracking devices. Additionally, user interface input devices may include medical imaging input devices, such as computed tomography, magnetic resonance imaging, position emission tomography, or medical ultrasonography devices. User interface input devices may also include audio input devices, such as MIDI keyboards, digital musical instruments and the like.

User interface output devices may include a display subsystem, indicator lights, or non-visual displays, such as audio output devices. The display subsystem may be a cathode ray tube (CRT), a flat-panel device, such as that using a liquid crystal display (LCD) or plasma display, a projection device, a touch screen, and the like. In general, use of the term “output device” is intended to include any type of device and mechanism for outputting information from computer system 800 to a user or other computer. For example, user interface output devices may include, without limitation, a variety of display devices that visually convey text, graphics and audio/video information, such as monitors, printers, speakers, headphones, automotive navigation systems, plotters, voice output devices, and modems.

Computer system 800 may comprise a storage subsystem 818 that provides a tangible, non-transitory, computer-readable storage medium for storing software and data constructs that provide the functionality of the embodiments described in this disclosure. The software can include programs, code modules, instructions, scripts, etc., that, when executed by one or more cores or processors of processing unit 804, provide the functionality described above. Storage subsystem 818 may also provide a repository for storing data used in accordance with the present disclosure.

As depicted in the example in FIG. 8, storage subsystem 818 can include various components, including a system memory 810, computer-readable storage media 822, and a computer readable storage media reader 820. System memory 810 may store program instructions, such as application programs 812, that are loadable and executable by processing unit 804. System memory 810 may also store data, such as program data 814, that is used during the execution of the instructions and/or data that is generated during the execution of the program instructions. Various programs may be loaded into system memory 810 including, but not limited to, client applications, Web browsers, mid-tier applications, relational database management systems (RDBMS), virtual machines, containers, etc.

System memory 810 may also store an operating system 816. Examples of operating system 816 may include various versions of Microsoft Windows®, Apple Macintosh®, and/or Linux operating systems, a variety of commercially available UNIX® or UNIX-like operating systems (including without limitation the variety of GNU/Linux operating systems, the Google Chrome® OS, and the like) and/or mobile operating systems, such as iOS, Windows® Phone, Android® OS, BlackBerry® OS, and Palm® OS operating systems. In certain implementations where computer system 800 executes one or more virtual machines, the virtual machines along with their guest operating systems (GOSs) may be loaded into system memory 810 and executed by one or more processors or cores of processing unit 804.

System memory 810 can come in different configurations depending upon the type of computer system 800. For example, system memory 810 may be volatile memory (such as random access memory (RAM)) and/or non-volatile memory (such as read-only memory (ROM), flash memory, etc.). Different types of RAM configurations may be provided, including a static random access memory (SRAM), a dynamic random access memory (DRAM), and others. In some implementations, system memory 810 may include a basic input/output system (BIOS) including basic routines that help to transfer information between elements within computer system 800 such as during start-up.

Computer-readable storage media 822 may represent remote, local, fixed, and/or removable storage devices plus storage media for temporarily and/or more permanently including and storing computer-readable information for use by computer system 800, including instructions executable by processing unit 804 of computer system 800.

Computer-readable storage media 822 can include any appropriate media known or used in the field, including storage media and communication media, such as but not limited to volatile and non-volatile, removable and non-removable media implemented in any method or technology for storage and/or transmission of information. This can include tangible, computer-readable storage media, such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible, computer-readable media.

By way of example, computer-readable storage media 822 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk, such as a CD ROM, DVD, and Blu-Ray® disk, or other optical media. Computer-readable storage media 822 may include, but is not limited to, Zip® drives, flash memory cards, universal serial bus (USB) flash drives, secure digital (SD) cards, DVD disks, digital video tape, and the like. Computer-readable storage media 822 may also include solid-state drives (SSD) based on non-volatile memory, such as flash-memory based SSDs, enterprise flash drives, solid state ROM, and the like, SSDs based on volatile memory, such as solid state RAM, dynamic RAM, static RAM, DRAM-based SSDs, magneto-resistive RAM (MRAM) SSDs, and hybrid SSDs that use a combination of DRAM and flash memory based SSDs. The disk drives and their associated, computer-readable media may provide non-volatile storage of computer-readable instructions, data structures, program modules, and other data for computer system 800.

Machine-readable instructions executable by one or more processors or cores of processing unit 804 may be stored on a non-transitory, computer-readable storage medium. A non-transitory, computer-readable storage medium can include physically tangible memory or storage devices that include volatile memory storage devices and/or non-volatile storage devices. Examples of non-transitory, computer-readable storage medium include magnetic storage media (e.g., disk or tapes), optical storage media (e.g., DVDs, CDs), various types of RAM, ROM, or flash memory, hard drives, floppy drives, detachable memory drives (e.g., USB drives), or other type of storage device.

Communications subsystem 824 provides an interface to other computer systems and networks. Communications subsystem 824 serves as an interface for receiving data from and transmitting data to other systems from computer system 800. For example, communications subsystem 824 may enable computer system 800 to connect to one or more devices via the Internet. In some embodiments, communications subsystem 824 can include radio frequency (RF) transceiver components to access wireless voice and/or data networks (e.g., using cellular telephone technology, advanced data network technology, such as 3G, 4G, or EDGE (enhanced data rates for global evolution), Wi-Fi (IEEE 802.11 family standards, or other mobile communication technologies, or any combination thereof), global positioning system (GPS) receiver components, and/or other components. In some embodiments, communications subsystem 824 can provide wired network connectivity (e.g., Ethernet) in addition to or instead of a wireless interface.

In some embodiments, communications subsystem 824 may also receive input communication in the form of structured and/or unstructured data feeds 826, event streams 828, event updates 830, and the like on behalf of one or more users who may use computer system 800.

By way of example, communications subsystem 824 may be configured to receive data feeds 826 in real time from users of social networks and/or other communication services, such as Twitter® feeds, Facebook® updates, web feeds, such as Rich Site Summary (RSS) feeds, and/or real-time updates from one or more third party information sources.

Additionally, communications subsystem 824 may be configured to receive data in the form of continuous data streams. The continuous data streams may include event streams 828 of real-time events and/or event updates 830 that may be continuous or unbounded in nature with no explicit end. Examples of applications that generate continuous data may include sensor data applications, financial tickers, network performance measuring tools (e.g., network monitoring and traffic management applications), clickstream analysis tools, automobile traffic monitoring, and the like.

Communications subsystem 824 may also be configured to output the structured and/or unstructured data feeds 826, event streams 828, event updates 830, and the like to one or more databases that may be in communication with one or more streaming data source computers coupled to computer system 800.

Computer system 800 can be one of various types, including a handheld portable device (e.g., an iPhone® cellular phone, an iPad® computing tablet, a PDA), a wearable device (e.g., a Google Glass® head mounted display), a PC, a workstation, a mainframe, a kiosk, a server rack, or any other data processing system.

Due to the ever-changing nature of computers and networks, the description of computer system 800 depicted in FIG. 8 is intended as a non-limiting example. Many other configurations having more or fewer components than the system depicted in FIG. 8 are possible. For example, customized hardware might also be used and/or particular elements might be implemented in hardware, firmware, software (including applets), or a combination. Furthermore, connection to other computing devices, such as network input/output devices, may be employed. Based on the disclosure and teachings provided herein, a person of ordinary skill in the art will appreciate other ways and/or methods to implement the various embodiments.

### 5. Miscellaneous; Extensions

Unless otherwise defined, all terms (including technical and scientific terms) are to be given their ordinary and customary meaning to a person of ordinary skill in the art, and are not to be limited to a special or customized meaning unless expressly so defined herein.

This application may include references to certain trademarks. Although the use of trademarks is permissible in patent applications, the proprietary nature of the marks should be respected and every effort made to prevent their use in any manner which might adversely affect their validity as trademarks.

Embodiments are directed to a system with one or more devices that include a hardware processor and that are configured to perform any of the operations described herein and/or recited in any of the claims below.

In an embodiment, one or more non-transitory computer readable storage media comprises instructions which, when executed by one or more hardware processors, cause performance of any of the operations described herein and/or recited in any of the claims.

In an embodiment, a method comprises operations described herein and/or recited in any of the claims, the method being executed by at least one device including a hardware processor.

Any combination of the features and functionalities described herein may be used in accordance with one or more embodiments. In the foregoing specification, embodiments have been described with reference to numerous specific details that may vary from implementation to implementation. The specification and drawings are, accordingly, to be regarded in an illustrative rather than a restrictive sense. The sole and exclusive indicator of the scope of patent protection, and what is intended by the applicants to be the scope of patent protection, is the literal and equivalent scope of the set of claims that issue from this application, in the specific form in which such claims issue, including any subsequent correction.

What is claimed is:

1. A method comprising:
supplying a first data center pod with a coolant liquid via a first coolant pipe assembly,
wherein the first data center pod comprises:
a plurality of racks storing computing devices;
a data center pod frame defining a plurality of compartments for storing the plurality of racks;
a plurality of wiring support members for supporting wiring connected to the computing devices; and
a coolant pipe support member supporting the first coolant pipe assembly, and
wherein supplying the first data center pod with the coolant liquid comprises:
supplying the coolant liquid to a first rack among the plurality of racks via a first valve along a first coolant pipe in the first coolant pipe assembly; and
supplying the coolant liquid to a second rack among the plurality of racks via the first valve and a second valve, and
isolating the first rack among the plurality of racks from a flow of the coolant liquid by closing the first valve and the second valve,
wherein the first coolant pipe assembly is configured to redirect the coolant liquid to the second rack through the first coolant pipe via at least a third valve.

2. The method of claim 1, wherein the first coolant pipe assembly comprises a plurality of coolant pipe segments connected together,
wherein the first coolant pipe assembly is configured to provide the coolant liquid to the first rack via a first connector located along a first pipe segment among the plurality of coolant pipe segments,
wherein the first pipe segment extends between the first valve and the second valve,
wherein the first coolant pipe assembly is configured to provide the coolant liquid to the second rack via a second connector located along a second pipe segment, and
wherein the second pipe segment extends between the second valve and the third valve.

3. The method of claim 2, wherein the first coolant pipe assembly comprises a loop configuration of pipe segments,
wherein at least one of closing the first valve and closing the second valve redirects the flow of the coolant liquid to the second rack from flowing in a first direction through the loop configuration to flowing in a second direction opposite the first direction.

4. The method of claim 2, further comprising:
prior to closing the first valve and the second valve: supplying the coolant liquid to the second pipe segment via the first valve and the second valve,
wherein at least one of closing the first valve and closing the second valve restricts the flow of the coolant liquid to the second pipe segment via the second valve,
wherein the second valve is at a first end of the second pipe segment, and
wherein the method further comprises:
responsive to closing the second valve: supplying the coolant liquid to the second pipe segment via a second end of the second pipe segment opposite the first end.

5. The method of claim 2, further comprising:
concurrently with: (a) isolating the first rack, and (b) redirecting the coolant liquid to the second rack via the third valve:
removing the first rack from the first data center pod;
inserting a third rack into the first data center pod;
connecting the third rack to the first pipe segment; and
opening the first valve to permit fluid flow to the first pipe segment.

6. The method of claim 1, wherein redirecting the coolant liquid to the second rack through the first coolant pipe via at least the third valve comprises:
opening a fourth valve connecting the first coolant pipe assembly of the first data center pod with a second coolant pipe assembly of a second data center pod to direct the coolant liquid to the second rack via the fourth valve and the third valve.

7. The method of claim 6, wherein the first data center pod includes a first cooling device that provides the coolant liquid to the first coolant pipe assembly,
wherein the second data center pod includes a second cooling device that provides the coolant liquid to the second coolant pipe assembly,
wherein opening the fourth valve causes the coolant liquid to flow from the second cooling device to the first coolant pipe assembly.

8. The method of claim 1, further comprising:
detecting a triggering event for triggering isolating the first rack from the flow of the coolant liquid,
wherein closing the first valve and the second valve are performed responsive to detecting the triggering event.

9. The method of claim 8, further comprising:
monitoring sensors in the first data center pod to measure characteristics of the plurality of racks,
wherein the triggering event corresponds to one or more measurements generated by the sensors exceeding one or more thresholds.

10. The method of claim 1, wherein the plurality of racks includes a first set of racks arranged in a first row and a second set of racks arranged in a second row parallel to the first row,
wherein the first coolant pipe assembly comprises:
a first coolant pipe side section extending along the first row and supplying the coolant liquid to the first set of racks; and
a second coolant pipe side section extending along the second row and supplying the coolant liquid to the second set of racks,
wherein a first end of the first coolant pipe side section is connected to a first end of the second coolant pipe side section by a first coolant pipe end section, and
wherein a second end of the first coolant pipe side section is connected to a second end of the second coolant pipe side section by a second coolant pipe end section.

11. The method of claim 10, wherein a cooling device is connected to the first coolant pipe end section, and
wherein supplying the first data center pod with the coolant liquid comprises supplying, by the cooling device, the coolant liquid to the first coolant pipe end section.

12. A data center system, comprising:
a first data center pod, comprising:
a first plurality of racks configured to store a plurality of computing devices;
a pod frame defining a plurality of compartments for storing the first plurality of racks;
a plurality of wiring support members for supporting wiring connected to the plurality of computing devices;
a coolant pipe support member supporting a first coolant pipe assembly; and
a first cooling device for supplying a coolant liquid to the first coolant pipe assembly,
wherein the first coolant pipe assembly comprises:
a first connector for connecting a first coolant pipe to a first rack among the first plurality of racks;
a second connector for connecting the first coolant pipe to a second rack among the first plurality of racks;
a first valve located along the first coolant pipe on a first side of the first connector;
a second valve located along the first coolant pipe on a second side of the first connector opposite the first side, the second valve located between the first connector and the second connector, wherein the second valve is located on a first side of the second connector; and
a third valve located on a second side of the second connector opposite the first side of the second connector,
wherein the second connector is in fluid communication with a coolant flow from the first cooling device via the second valve and via the third valve.

13. The data center system of claim 12, wherein the first coolant pipe assembly comprises a plurality of pipe segments connected between a plurality of valves,
wherein the plurality of valves are located on opposing sides of a plurality of connectors that connect the first plurality of racks to the first coolant pipe assembly.

14. The data center system of claim 12, wherein the first plurality of racks includes a first set of racks arranged in a first row and a second set of racks arranged in a second row parallel to the first row,
wherein the first coolant pipe assembly comprises:
a first coolant pipe side section extending along the first row;
a first set of connectors connecting the first coolant pipe side section to the first set of racks to allow the coolant liquid to flow between the first coolant pipe side section and the first set of racks;
a second coolant pipe side section extending along the second row and supplying the coolant liquid to the second set of racks; and
a second set of connectors connecting the second coolant pipe side section to the second set of racks to allow the coolant liquid to flow between the second coolant pipe side section and the second set of racks.

15. The data center system of claim 14, wherein a first end of the first coolant pipe side section is connected to a first end of the second coolant pipe side section by a first coolant pipe end section, and
wherein a second end of the first coolant pipe side section is connected to a second end of the second coolant pipe side section by a second coolant pipe end section.

16. The data center system of claim 12, further comprising:
a second data center pod, comprising:
a second plurality of racks;
a second coolant pipe assembly connected to the second plurality of racks to provide the coolant liquid to the second plurality of racks; and
a second cooling device for supplying the coolant liquid to the second coolant pipe assembly; and
a fourth valve connecting the first coolant pipe assembly to the second coolant pipe assembly to selectively allow the coolant liquid to flow between the first coolant pipe assembly and the second coolant pipe assembly.

17. The data center system of claim 12, further comprising:
a controller configured to generate control signals to open and close the first valve, the second valve, and the third valve.

18. The data center system of claim 17, further comprising:
a set of sensors configured to monitor characteristics associated with the first plurality of racks,
wherein the controller is configured to generate the control signals based on measurements generated by the set of sensors.

19. The data center system of claim 12, wherein the first plurality of racks comprises a first row of racks and a second row of racks arranged in parallel to the first row of racks,
wherein the first data center pod further comprises a plurality of panels supported by the pod frame,
wherein the plurality of panels is configured to form an enclosed space around an aisle between the first row of racks and the second row of racks,
wherein the plurality of panels includes a first panel located at a height above the first plurality of racks at one end of the aisle,
wherein the first panel includes a hole with a shape corresponding to a shape of the first coolant pipe, and
wherein the first coolant pipe passes through the hole into the enclosed space formed by the plurality of panels.

20. The data center system of claim 19, wherein the first cooling device is located outside the enclosed space formed by the plurality of panels, and
wherein the first cooling device is connected to the first coolant pipe assembly outside the enclosed space formed by the plurality of panels.
